(19) United States
(12) Patent Application Publication
(10) Pub. No.: US 2012/0080731 A1
(43) Pub. Date: Apr. 5, 2012

(54) PHOTODETECTOR ISOLATION IN IMAGE SENSORS

(76) Inventors: Hung Q. Doan, Rochester, NY (US); Eric G. Stevens, Webster, NY (US); Robert M. Guidash, Rochester, NY (US)

(21) Appl. No.: 12/894,262

(22) Filed: Sep. 30, 2010

(51) Int. Cl. H01L 27/146

(52) U.S. Cl. 257/292; 257/E27.133

(57) ABSTRACT

A first shallow trench isolation region is disposed in the silicon semiconductor layer laterally adjacent to a photodetector while a second shallow trench isolation region is disposed in the silicon semiconductor layer laterally adjacent to other electrical components in a pixel. The first and second shallow trench isolation regions each include a trench disposed in the silicon semiconductor layer that is filled with a dielectric material. An isolation layer having the second conductivity is disposed only along a portion of a bottom and only along a sidewall of the trench immediately adjacent to the photodetector. The isolation layer is not disposed along the other portion of the bottom and along the other sidewall of the trench adjacent the photodetector. The isolation layer is not disposed along the bottom and sidewalls of the trench adjacent to the other electrical components.

### TECHNICAL FIELD

The present invention relates to image sensors for use in digital cameras and other types of image capture devices, and more particularly to Complementary Metal Oxide Semiconductors (CMOS) image sensors. Still more particularly, the present invention relates to photodiode isolation in CMOS image sensors and a method for producing such isolation.

### BACKGROUND

Image sensors capture images using thousands to millions of pixels that are typically arranged in an array. FIG. 1 depicts a top view of a pixel commonly used in a CMOS image sensor in accordance with the prior art. Pixel 100 includes photodetector (PD) 102 that collects charge in response to incident light. Before the charge is read out of photodetector 102, an appropriate signal is applied to the gate (RG) of a reset transistor via contact 104 to reset a charge-to-voltage conversion region (FD) 106 to a known potential VDD. Charge is then transferred from the photodetector 102 to the charge-to-voltage conversion region 106 when a a transfer transistor is enabled through the application of an appropriate signal to a transfer gate (TG) using contact 108. The charge-to-voltage conversion region 106 is used to convert the collected charge into a voltage.

A gate 110 of an amplifier transistor (SF) is connected via signal line 111 to charge-to-voltage conversion region 106. To transfer the voltage from the charge-to-voltage conversion region 106 to an output VOUT, an appropriate signal is applied to a gate of a row select transistor (RS) via contact 112. Activation of the row select transistor enables the amplifier transistor (SF), which in turn transfers the voltage from charge-to-voltage converter (FD) to VOUT. Shallow trench isolation regions (STI) surround the photodetector (PD) and the pixel 100 to electrically isolate the pixel from adjacent pixels in the image sensor. An n-type isolation layer 114 surrounds the STI regions, as will be described in more detail in conjunction with FIGS. 2 and 3.

FIG. 2 illustrates a cross-sectional schematic view along line A-A in FIG. 1 depicting the prior art pixel structure. Pixel 100 includes the transfer gate (TG), charge-to-voltage conversion region 106, and photodetector 102. The photodetector 102 is implemented as a pinned photodiode consisting of n+ pinning layer 200 and p-type storage region 202 formed within n-type layer 204. N-type layer 204 is disposed over substrate layer 206.

Shallow trench isolation regions (STI) 208 are formed laterally adjacent to opposite sides of photodetector 102 and surround the photodetector. STI 208 is also formed laterally adjacent to the charge-to-voltage conversion region 106, with the transfer gate (TG) positioned between photodetector 102 and charge-to-voltage conversion region 106. STI regions 208 include a trench formed in the n-type layer 204 that is filled with a dielectric material 210. The n-type isolation layer 114 surrounds the sidewalls and bottom of each trench. Isolation layer 114 is typically formed by implanting an n-type dopant into the sidewalls and bottoms of the trenches prior to filling the trenches with the dielectric material 210.

FIG. 3 depicts a cross-sectional schematic view along line B-B in FIG. 1 depicting the prior art pixel structure. STI 208 are formed laterally adjacent to and surround photodetector 102. STI 208 is also formed laterally adjacent to charge-to-voltage conversion region 106. N-type isolation layer 114 surrounds the sidewalls and bottom of the trenches.

The shallow n+ implant of isolation layer 114 can cause the peripheral capacitance of the charge-to-voltage conversion region 106 to increase, and can cause higher dark current or point defects due to the p+/n+ diode junction formed by the n-type isolation layer and the p-type charge-to-voltage conversion region 106. In addition the n-type isolation layer 114 that is laterally adjacent to the one or more transistors in pixel 100, such as the amplifier transistor (SF), can reduce the effective width of the transistors. This can cause narrow channel effects and require the design of a wider transistor that in turn reduces the fill factor of the pixel.

### SUMMARY

An image sensor includes an array of pixels that form an imaging area. At least one pixel includes a photodetector and a charge-to-voltage conversion region disposed in a silicon semiconductor layer. The photodetector includes a storage region of a first conductivity type that is disposed in the silicon semiconductor layer having a second conductivity type. The charge-to-voltage conversion region is of the first conductivity type and can be electrically connected to the storage region by a transfer gate positioned between the storage region and the charge-to-voltage conversion region.

Shallow trench isolation regions are formed laterally adjacent to or surround the photodetector, the charge-to-voltage conversion region, and other features and components in each pixel. The shallow trench isolation regions each include a trench disposed in the silicon semiconductor layer that is filled with a dielectric material. A shallow trench isolation region is laterally adjacent to and surrounds each photodetector. An isolation layer having the second conductivity is disposed along only a portion of the bottom of the trench and only along the sidewall of the trench that is immediately adjacent to a photodetector. The isolation layer is not disposed along the remaining bottom portion and the opposing sidewall of the trench.

Another shallow trench isolation region is laterally adjacent to or surrounds the other electrical components in each pixel. The other electrical components can include a charge-to-voltage conversion region and source/drain implant regions for one or more transistors. An isolation layer is not disposed along the bottom and sidewalls of the trenches adjacent to the other electrical components in the pixels.

### BRIEF DESCRIPTION OF THE DRAWINGS

Embodiments of the invention are better understood with reference to the following drawings. The elements of the drawings are not necessarily to scale relative to each other.

FIG. 1 depicts a top view of a pixel commonly used in a CMOS image sensor in accordance with the prior art;

FIG. 2 illustrates a cross-sectional view along line A-A in FIG. 1 depicting the prior art pixel structure;

FIG. 3 depicts a cross-sectional view along line B-B in FIG. 1 depicting the prior art pixel structure;

FIG. 4 is a simplified block diagram of an image capture device in an embodiment in accordance with the invention;

FIG. 5 is a simplified block diagram of an image sensor suitable for use as image sensor 406 shown in FIG. 4 in an embodiment in accordance with the invention;

FIG. 6 illustrates a top view of two exemplary pixels each suitable for use as pixel 502 shown in FIG. 5 in an embodiment in accordance with the invention;

FIG. 7 depicts a cross-sectional view along line C-C in FIG. 6;

FIG. 8 illustrates a cross-sectional view along line D-D in FIG. 6;

FIG. 9 is a flowchart of a method for fabricating a portion of an imaging area in an image sensor in an embodiment in accordance with the invention;

FIGS. 10A-10D depict a method for producing the STI regions and isolation layer 714 shown in FIG. 7 in an embodiment in accordance with the invention;

FIGS. 11A-11B illustrate a method for producing the STI regions and isolation layer 714 shown in FIG. 8 in an embodiment in accordance with the invention; and

FIG. 12 is a cross-section view of an alternate pixel structure in an embodiment in accordance with the invention.

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected, or an indirect connection through one or more passive or active intermediary devices. The term “circuit” means either a single component or a multiplicity of components, either active or passive, that are connected together to provide a desired function. The term “signal” means at least one current, voltage, charge, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the term “substrate layer” is to be understood as a semiconductor-based material including, but not limited to, silicon, silicon-on-insulator (SOI) technology, silicon-on-sapphire (SOS) technology, doped and undoped semiconductors, epitaxial layers or well regions formed on a semiconductor substrate, and other semiconductor structures.

Referring to the drawings, like numbers indicate like parts throughout the views.

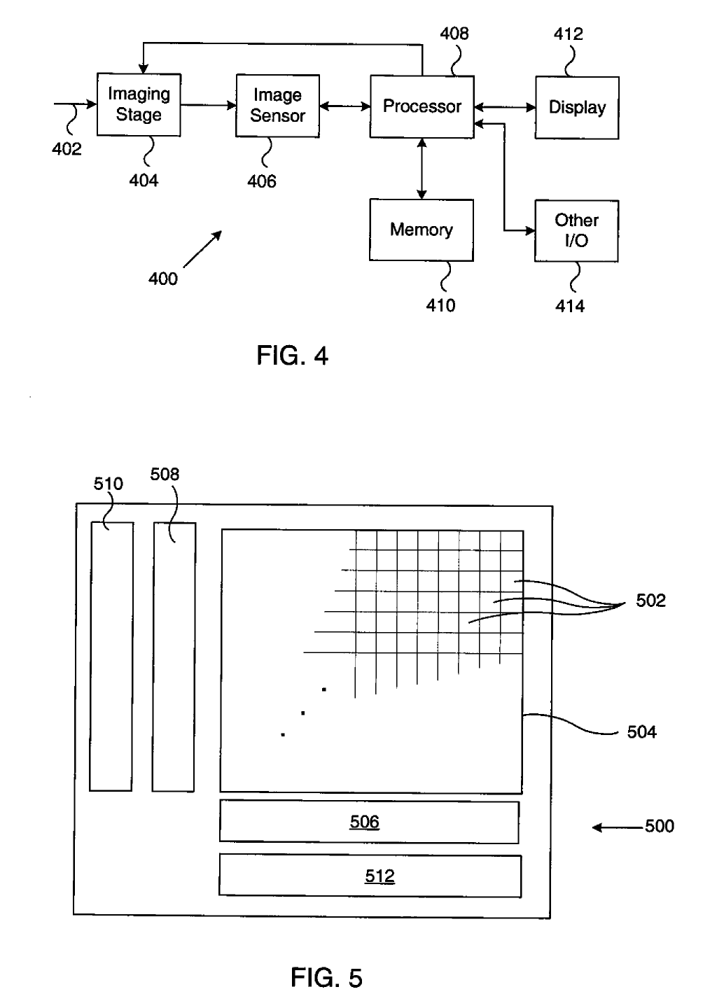

FIG. 4 is a simplified block diagram of an image capture device in an embodiment in accordance with the invention. Image capture device 400 is implemented as a digital camera in FIG. 4. Those skilled in the art will recognize that a digital camera is only one example of an image capture device that can utilize an image sensor incorporating the present invention. Other types of image capture devices, such as, for example, cell phone cameras and digital video camcorders, can be used with the present invention.

In digital camera 400, light 402 from a subject scene is input to an imaging stage 404. Imaging stage 404 can include conventional elements such as a lens, a neutral density filter, an iris and a shutter. Light 402 is focused by imaging stage 404 to form an image on image sensor 406. Image sensor 406 captures one or more images by converting the incident light into electrical signals. Digital camera 400 further includes processor 408, memory 410, display 412, and one or more additional input/output (I/O) elements 414. Although shown as separate elements in the embodiment of FIG. 4, imaging stage 404 may be integrated with image sensor 406, and possibly one or more additional elements of digital camera 400, to form a compact camera module.

Processor 408 may be implemented, for example, as a microprocessor, a central processing unit (CPU), an application-specific integrated circuit (ASIC), a digital signal processor (DSP), or other processing device, or combinations of multiple such devices. Various elements of imaging stage 404 and image sensor 406 may be controlled by timing signals or other signals supplied from processor 408.

Memory 410 may be configured as any type of memory, such as, for example, random access memory (RAM), read-only memory (ROM), Flash memory, disk-based memory, removable memory, or other types of storage elements, in any combination. A given image captured by image sensor 406 may be stored by processor 408 in memory 410 and presented on display 412. Display 412 is typically an active matrix color liquid crystal display (LCD), although other types of displays may be used. The additional I/O elements 414 may include, for example, various on-screen controls, buttons or other user interfaces, network interfaces, or memory card interfaces.

It is to be appreciated that the digital camera shown in FIG. 4 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

Referring now to FIG. 5, there is shown a simplified block diagram of an image sensor suitable for use as image sensor 406 shown in FIG. 4 in an embodiment in accordance with the invention. Image sensor 500 typically includes an array of pixels 502 that form an imaging area 504. Image sensor 500 further includes column decoder 506, row decoder 508, digital logic 510, and analog or digital output circuits 512. Image sensor 500 is implemented as a back or front-illuminated Complementary Metal Oxide Semiconductor (CMOS) image sensor in an embodiment in accordance with the invention. Thus, column decoder 506, row decoder 508, digital logic 510, and analog or digital output circuits 512 are implemented as standard CMOS electronic circuits that are electrically connected to imaging area 504.

Functionality associated with the sampling and readout of imaging area 504 and the processing of corresponding image data may be implemented at least in part in the form of software that is stored in memory 410 and executed by processor 408 (see FIG. 4). Portions of the sampling and readout circuitry may be arranged external to image sensor 406, or formed integrally with imaging area 504, for example, on a common integrated circuit with photodetectors and other elements of the imaging area. Those skilled in the art will recognize that other peripheral circuitry configurations or architectures can be implemented in other embodiments in accordance with the invention.

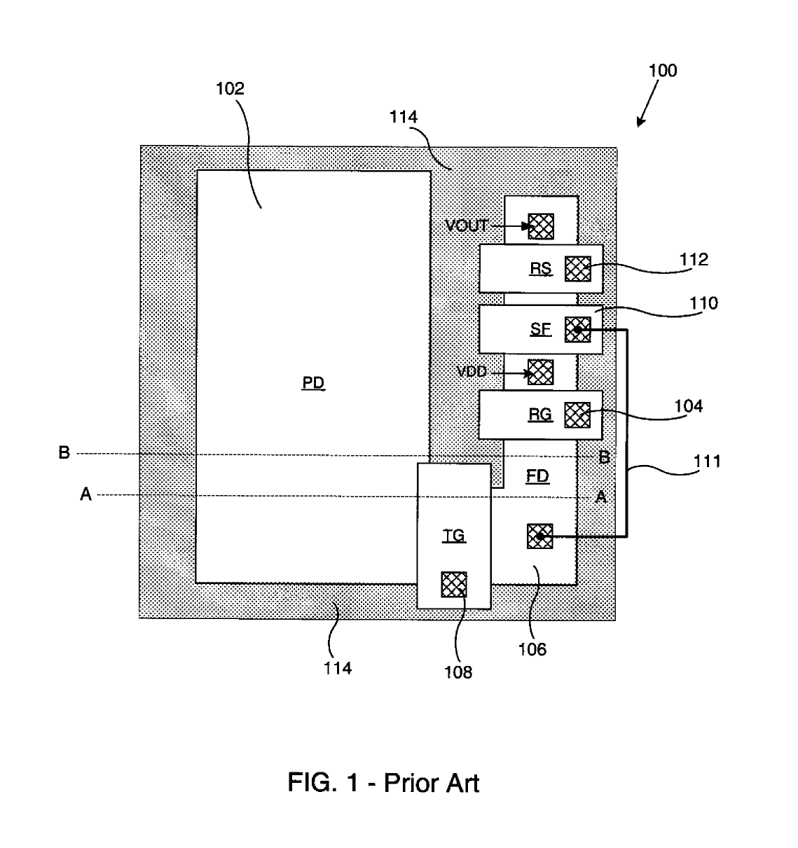

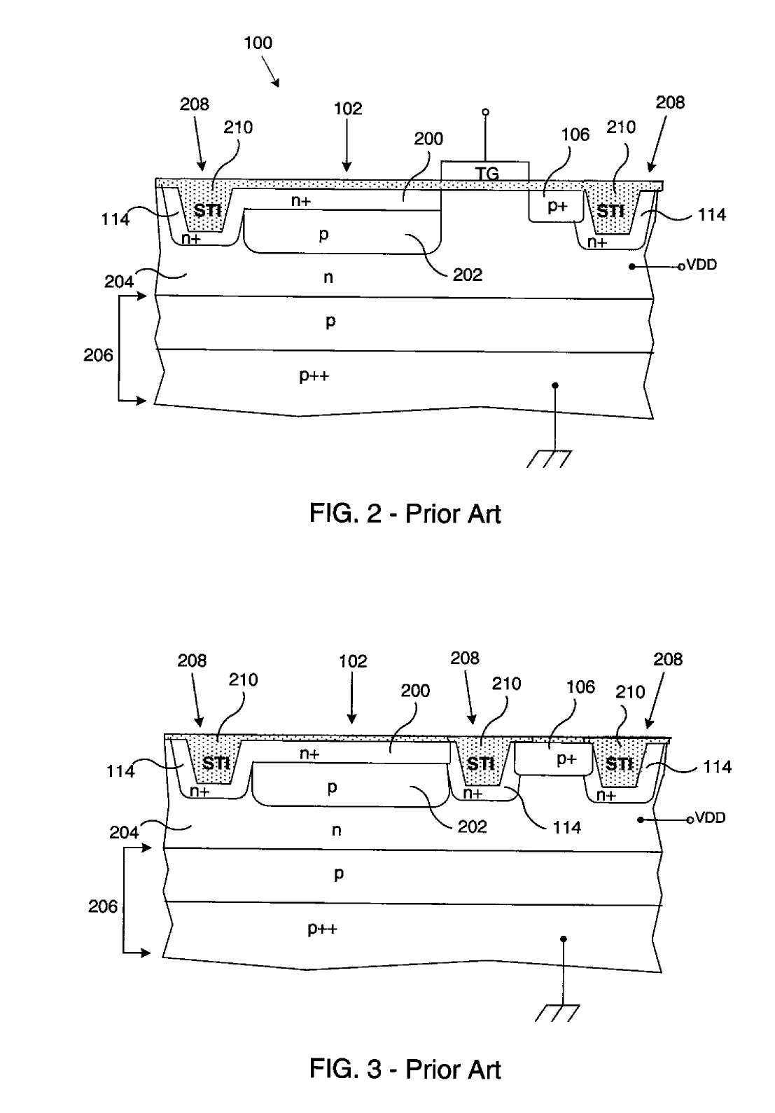

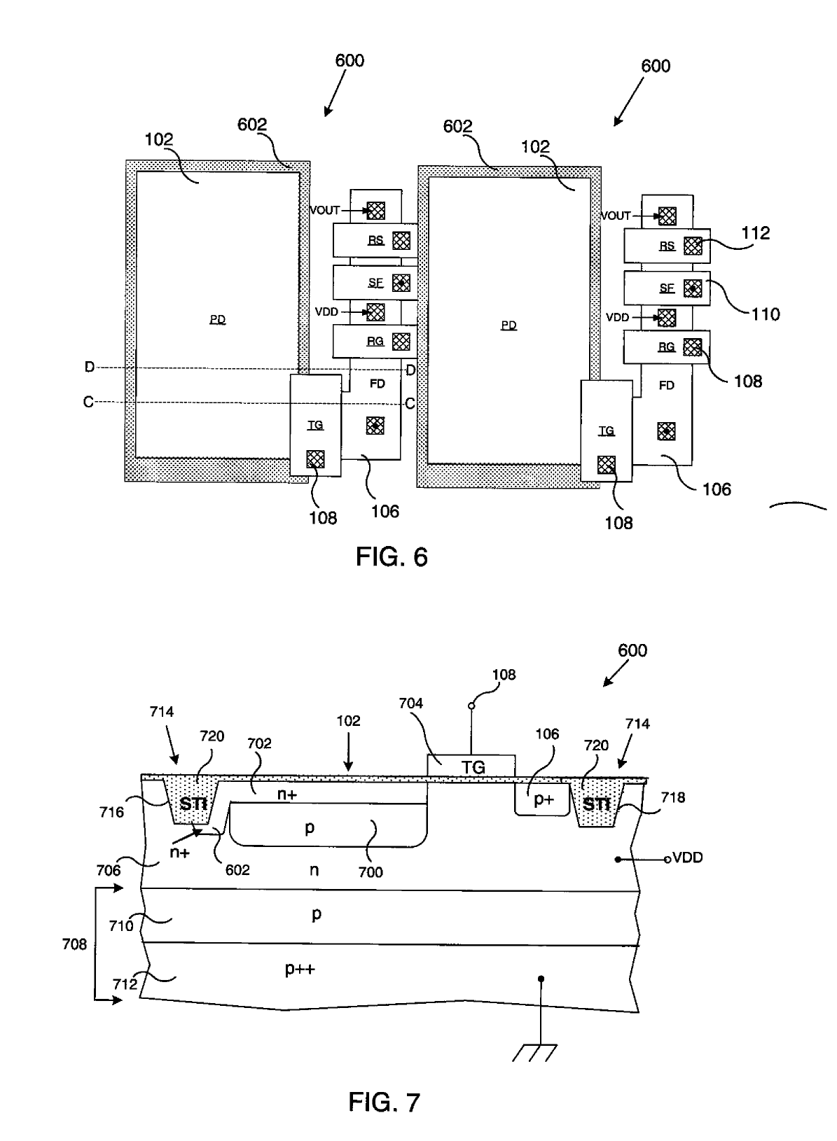

FIG. 6 illustrates a top view of two exemplary adjacent pixels suitable for use as pixels 502 shown in FIG. 5 in an embodiment in accordance with the invention. Pixels 600 each include a photodetector (PD) 102, transfer transistor with transfer gate (TG) and contact 108, charge-to-voltage conversion region (FD) 106, reset transistor with reset gate (RG) 104, amplifier transistor (SF) with gate 110, row select transistor with gate and contact 112, VDD, and VOUT as shown in FIG. 1. Signal line 111 connecting charge-to-voltage conversion region 106 to gate 110 of amplifier transistor (SF) is omitted in FIG. 6 for simplicity. Amplifier transistor (SF) is implemented as a source-follower transistor and charge-to-voltage conversion region as a floating diffusion in an embodiment in accordance with the invention.

The transfer transistor, charge-to-voltage conversion region 106, reset transistor, row select transistor, amplifier transistor, VDD, and VOUT are examples of electrical components that can be included in a pixel 600. Other embodiments in accordance with the invention can omit one or more of the illustrated electrical components. Alternatively, a pixel can include fewer, additional or different types of electrical components.

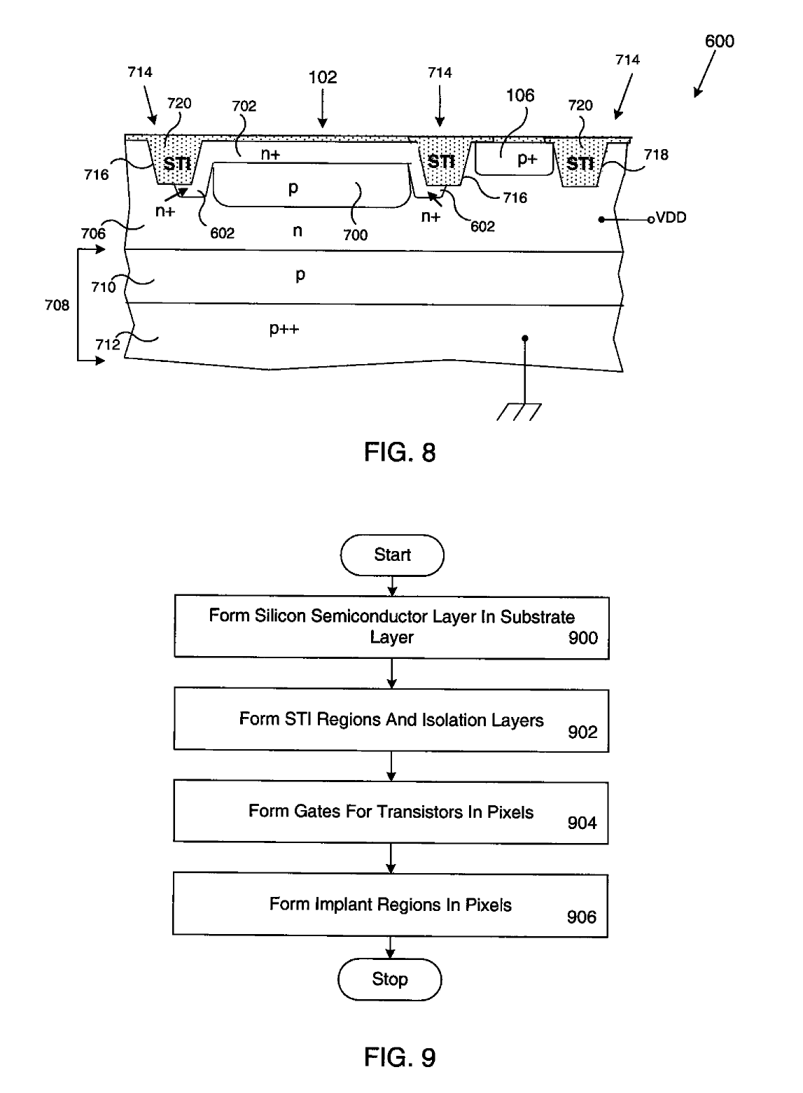

Charge collection and readout from pixels 600 is the same as that described with reference to FIG. 1. The shallow trench isolation regions (STI) surround photodetectors 102 and other electrical components as in the prior art, but the n-type isolation layer 602 surrounds only portions of the STI regions immediately adjacent the photodetectors 102, as will be described in more detail in conjunction with FIGS. 7 and 8.

FIG. 7 depicts a cross-sectional view along line C-C in FIG. 6. Pixel 600 includes storage region 700 and pinning layer 702 that together form photodetector 102 in an embodiment in accordance with the invention. In the illustrated embodiment, storage region 700 is doped with one or more dopants having a p conductivity type while pinning layer 702 is doped with a dopant or dopants having an n conductivity type.

Pixel 600 further includes charge-to-voltage conversion region 106. Transfer gate (TG) 704 is disposed between photodetector 102 and charge-to-voltage conversion region 106. Charge collected in storage region 700 transfers to charge-to-voltage conversion region 106 when an appropriate signal is applied to contact 108.

Photodetector 102 and charge-to-voltage conversion region 106 are disposed in silicon semiconductor layer 706. Silicon semiconductor layer 706 has an n conductivity type and may be implemented as a layer that spans an imaging area (e.g., imaging area 504) or as a well. Voltage supply VDD is connected to silicon semiconductor layer 706.

Silicon semiconductor layer 706 is disposed over substrate layer 708. Substrate layer 708 is implemented as an epitaxial layer 710 disposed over a substrate 712 in the FIG. 7 embodiment. Both epitaxial layer 710 and substrate 712 have a p conductivity type in an embodiment in accordance with the invention. Substrate 712 can be implemented as a bulk substrate having an n conductivity type in another embodiment in accordance with the invention.

Shallow trench isolation regions (STI) 714 are disposed in silicon semiconductor layer 706. Each STI region includes a trench 716, 718 that is filled with a dielectric material 720. An isolation layer 602 having an n conductivity type only partially surrounds the STI region 714 that is immediately adjacent to and surrounds the photodetector 102. Isolation layer 602 is disposed along a portion of the bottom trench 716 and only one side of the trench 716. In particular, isolation layer 602 is disposed along the portion of the bottom and the side of trench 716 that is immediately adjacent to storage region 700 and pinning layer 702.

Forming isolation layer 602 only along only a portion of the bottom and along the sidewall of trench 716 immediately adjacent to photodetector 102 suppresses dark current of the STI sidewall or interface that is adjacent to the photodetector. Additionally, isolation layer 602 is not disposed along the remaining bottom portion and other sidewall of trench 716, and not along the sidewalls and bottom of trench 718 of the STI region immediately adjacent to charge-to-voltage conversion region 106. Because isolation layer 602 is missing from these regions, the capacitance of charge-to-voltage conversion region 106 and the characteristics of the other transistors (e.g., reset transistor, source follower transistor, row select transistor) in pixel 600 are not adversely affected by isolation layer 602. Another advantage of removing the n+ isolation layer 602 from the sidewalls and bottom of trench 718 is the increase in the field effect transistor (FET) effective width. The FET width can be physically drawn smaller, which allows the width of photodetector 102 to be drawn bigger, thereby increasing pixel fill factor.

Referring now to FIG. 8, there is shown a cross-sectional view along line D-D in FIG. 6. Shallow trench isolation regions 714 are disposed in silicon semiconductor layer 706. STI regions 714 immediately adjacent to and surrounding photodetector 102 include isolation layer 602 having an n conductivity type. Isolation layer 602 only partially surrounds the STI regions 714 immediately adjacent to photodetector 102. Isolation layer 602 is disposed along the portion of the bottom and the side of trench 716 that is immediately adjacent to storage region 700 and pinning layer 702.

Isolation layer 602 is not disposed along the portion of the bottom and the other sidewall of trench 716 that is not immediately adjacent to photodetector 102. Isolation layer 602 is also not disposed along the sidewalls and bottom of trench 718.

FIG. 9 is a flowchart of a method for fabricating a portion of an imaging area in an image sensor in an embodiment in accordance with the invention. Initially, silicon semiconductor layer 706 is formed in substrate layer 708 (block 900). Silicon semiconductor layer 706 is formed in an epitaxial layer (e.g., epitaxial layer 710) when the substrate layer includes an epitaxial layer disposed over a substrate.

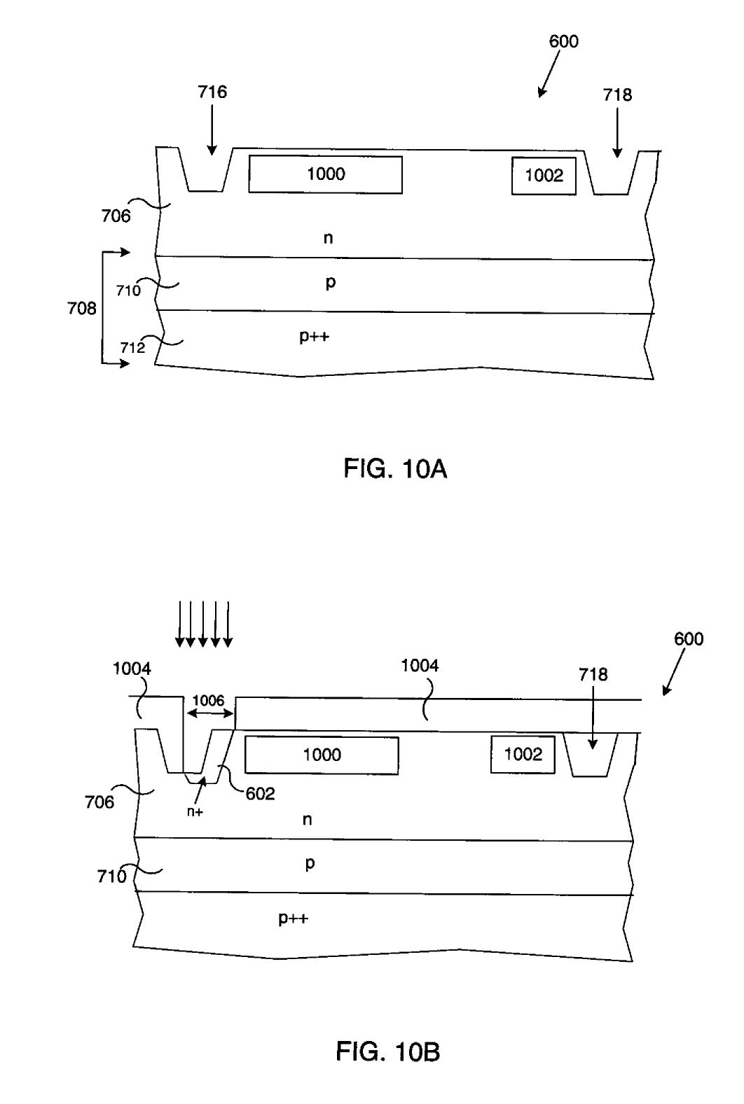

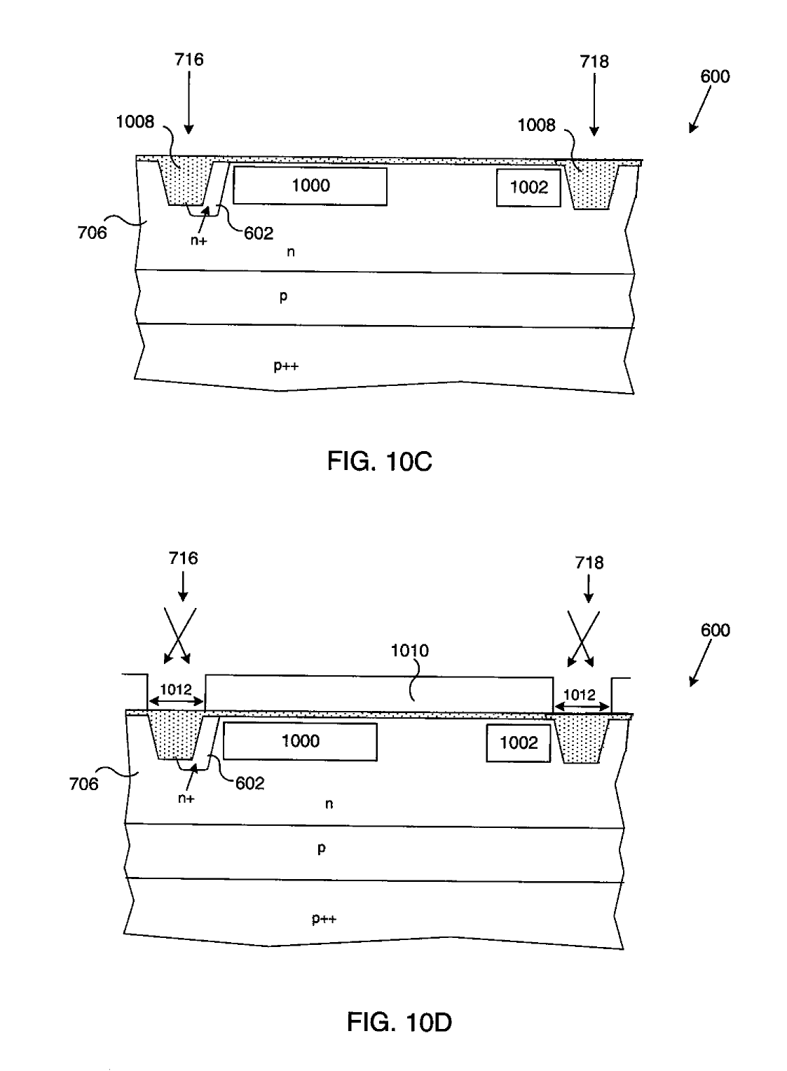

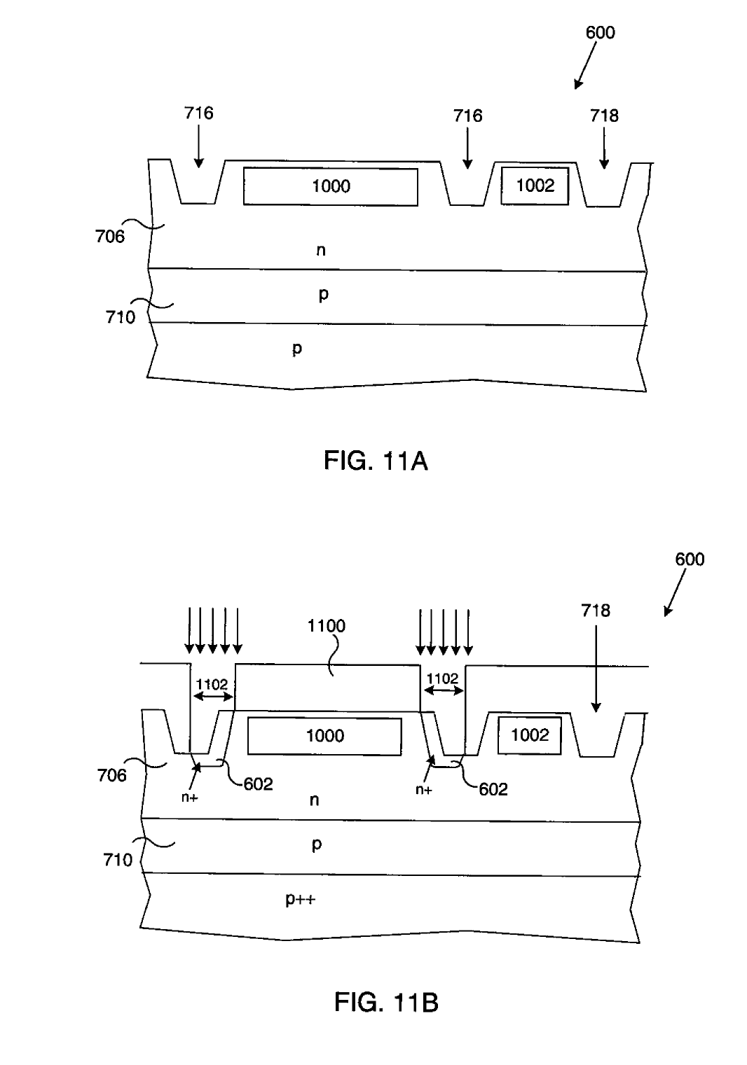

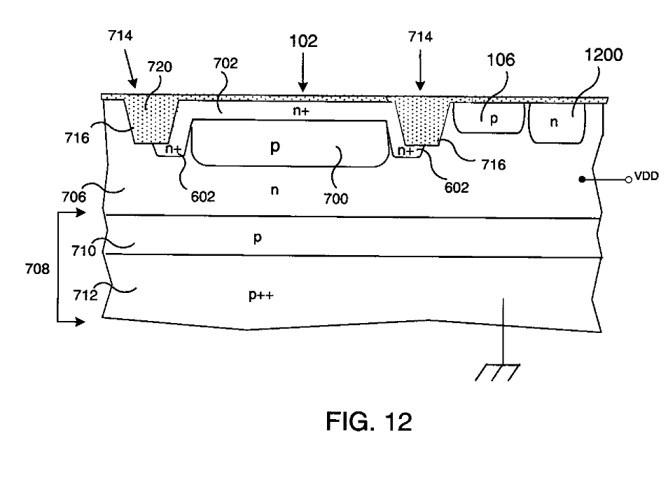

Next, as shown in block 902, STI regions 714 and isolation layer 602 are formed in silicon semiconductor layer 706. A process for producing STI regions 714 and isolation layer 602 is described in more detail in conjunction with FIGS. 10 and 11.

The gates for the transistors in the pixels are then formed, as shown in block 904. The gates can include the transfer gate (TG), the reset gate (RG), a gate of an amplifier transistor, and a gate of a row select transistor in an embodiment in accordance with the invention.

Next, as shown in block 906, the implant regions are formed. The implant regions include the storage region 700, charge-to-voltage conversion region 106, other source/drain regions, and the pinning layer 702 in an embodiment in accordance with the invention.

Those skilled in the art will recognize that other features and components of a pixel or imaging area are produced before, simultaneously with, or after the processes illustrated in FIG. 9. Moreover, features and components outside of the imaging area (e.g., area 504 in FIG. 5) can be fabricated before, simultaneously with, or after the processes illustrated in FIG. 9.

FIGS. 10A-10D depict a method for producing the STI regions and isolation layer 714 shown in FIG. 7 in an embodiment in accordance with the invention. The processes shown in FIGS. 10A-10D are not meant to illustrate all of the fabrication techniques for an image sensor or for a pixel. Those skilled in the art will recognize that other processes may be implemented in between the techniques shown in FIGS. 10A-10D.

FIG. 10A illustrates the pixel after n-type silicon semiconductor layer 706 is formed in p-type epitaxial layer 710 and after trenches 716, 718 are formed in layer 706. N-type silicon semiconductor layer 706 is produced by implanting a dopant having an n conductivity type into epitaxial layer 710. Trenches 716, 718 are formed by etching the n-type layer 706 using techniques known in the art.

Box 1000 represents an area in silicon semiconductor layer 706 where a photodetector will subsequently be formed. Box 1002 represents an area in silicon semiconductor layer 706 where a charge-to-voltage conversion region will subsequently be formed. As shown in FIG. 9, the photodetectors and other implanted regions, such as charge-to-voltage conversion and source/drain implant regions, are typically formed after the STI regions and gates have been formed.

A masking layer 1004 is then formed over pixel 600 and patterned to produce opening 1006 (FIG. 10B). Opening 1006 exposes a portion of trench 716 and n-type silicon semiconductor layer 706. The portion of the bottom of trench 716 and the sidewall of trench 716 exposed in openings 1102 are the portions of the trench 716 that are immediately adjacent to the yet-to-be-formed PD (represented by box 1000). An n-type dopant is implanted into opening 1006, as represented by the arrows. The n-type dopant typically has a high concentration of dopants. The implanted dopants form n-type isolation layer 602 along a portion of the bottom of trench 716 and the sidewall of trench 716 immediately adjacent to box 1000.

The masking layer 1004 is then removed and a dielectric material 1008 formed over the surface of n-type silicon semiconductor layer 706 to fill trenches 716, 718. The dielectric material 1008 is removed from the surface of n-type layer 706 until the dielectric material 1008 only fills trenches 716, 718. These processes are illustrated in FIG. 10C.

A masking layer 1010 is then formed over pixel 600 and patterned to produce openings 1012 (FIG. 10D). An n-type dopant is implanted into openings 1012, as represented by the arrows. The n-type dopant typically has a lower concentration of dopants than the dopants implanted in FIG. 10B. The implanted dopants passivate the interface between the sidewall surfaces and the n-type silicon semiconductor layer 706 and n-type isolation layer 602. The process depicted in FIG. 10D is optional and is not performed in other embodiments in accordance with the invention.

Referring now to FIGS. 11A-11B, there is shown a method for producing the STI regions 714 and isolation layer 602 shown in FIG. 8 in an embodiment in accordance with the invention. FIG. 11A depicts the pixel after n-type silicon semiconductor layer 706 is formed in p-type epitaxial layer 710 and after trenches 716, 718 are formed in layer 706. A masking layer 1100 is then formed over pixel 600 and patterned to produce openings 1102 (FIG. 11B). Openings 1102 expose a portion of trench 716 and n-type silicon semiconductor layer 706. The portion of the bottom of trench 716 and the sidewall of trench 716 exposed in openings 1102 are the portions of the trench 716 that are immediately adjacent to the yet-to-be-formed PD (represented by box 1000). An opening is not formed for trench 718 and trench 718 remains covered by masking layer 1100.

An n-type dopant is then implanted into silicon semiconductor layer 706 through openings 1102, as represented by the arrows. The n-type dopant typically has a high concentration of dopants. The implanted dopants form n-type isolation layer 602 along only the portion of the bottom of trench 716 and the one sidewall of the trench 716. Isolation layer 602 is formed in silicon semiconductor layer 706 immediately adjacent to the area where the photodetector will be formed.

The dopants are not implanted into the other portion of trench 716 and into the sidewall and bottom of trench 718 because the other portion of trench 716 and trench 718 are covered by masking layer 1100. Thus, an n-type isolation layer is not formed along the other portion of the bottom of trench 716, the sidewall of trench 716 not immediately adjacent to the area where the photodetector will be formed, and not along the sidewalls and bottom of trench 718.

As previously described, the dopants that form isolation layer 602 are typically implanted into the trenches before the dielectric layer is disposed in the trenches. Generally, the isolation layer implant is performed only in the imaging area of the image sensor (e.g., imaging area 504 in FIG. 5). The implant in the imaging area is an un-patterned or unmasked implant, meaning all of the STI regions in the imaging area receive the isolation layer implant. A patterned masking layer is used to cover only the areas outside of the imaging area during the isolation layer implant. Thus, the present invention does not increase fabrication costs by using a masking layer (layer 1004 in FIG. 10B; layer 1100 in FIG. 11) in the imaging area because the masking layer can be the same masking layer as the layer used to cover the areas outside of the imaging area.

FIG. 12 is a cross-section view of an alternate pixel structure in an embodiment in accordance with the invention. The pixel structure shown in FIG. 12 is the same as the pixel structure depicted in FIG. 8, except for the use of a well 1200 instead of an STI region. Well 1200 is doped with one or more dopants having an n conductivity type in the illustrated embodiment. Well 1200 is disposed in silicon semiconductor layer 706 laterally adjacent to charge-to-voltage conversion region 106 (on the side opposite STI region 714). Well 1200 is used to isolate charge-to-voltage conversion region 106 from other charge-to-voltage conversion regions and components in adjacent pixels. As with the FIG. 8 embodiment, the n+ isolation layer 602 does not reside around well 1200 and the portion of trench 716 that is immediately adjacent to charge-to-voltage conversion region 106.

The invention has been described in detail with particular reference to certain preferred embodiments thereof, but it will be understood that variations and modifications can be effected within the spirit and scope of the invention. For example, the features of pixel 600 have been described with reference to particular conductivity types. Opposite conductivity types can be used in other embodiments in accordance with the invention. Additionally, some of the features illustrated in pixel 600 can be omitted or shared in other embodiments in accordance with the invention. For example, pinning layer 702 does not have to be included in the pixels. Amplifier transistor (SF) or charge-to-voltage conversion region 106 can be shared by two or more pixels in other embodiments in accordance with the invention.

And even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

100 pixel
102 photodetector
104 contact
106 charge-to-voltage conversion region
108 contact
110 gate of source follower transistor
111 signal line
112 contact
114 isolation layer
200 pinning layer
202 storage region
204 layer
206 substrate layer
208 shallow trench isolation
210 dielectric material
400 image capture device
402 light
404 imaging stage
406 image sensor
408 processor
410 memory
412 display
414 other input/output (I/O)
500 image sensor
502 pixel
504 imaging area
506 column decoder
508 row decoder
510 digital logic
512 analog or digital output circuits
600 pixel
602 isolation layer
700 storage region
702 pinning layer
704 transfer gate
706 silicon semiconductor layer
708 substrate layer
710 epitaxial layer
712 substrate
714 shallow trench isolation
716 trench
718 trench
720 dielectric material
1000 area where photodetector will be formed
1002 area where charge-to-voltage conversion region will be formed
1004 masking layer
1006 opening
1008 dielectric material
1010 masking layer
1012 opening
1100 masking layer
1102 opening
1200 well
RG reset gate
RS row select transistor
SF amplifier transistor
STI shallow trench isolation
TG transfer gate
VDD voltage supply
VOUT output

1. An image sensor comprising an imaging area having a plurality of pixels with at least one pixel comprising:
a photodetector including a storage region of a first conductivity type disposed in a layer of a second conductivity type;
a first shallow trench isolation region disposed in the layer of the second conductivity type laterally adjacent to the storage region, wherein the first shallow trench isolation region comprises a trench formed in the layer of the second conductivity type that is filled with a dielectric material; and
an isolation layer of the second conductivity type disposed only partially along a bottom of the trench and only along a sidewall of the trench immediately adjacent to the storage region.

2. The image sensor as in claim 1, further comprising a charge-to-voltage conversion region of the first conductivity type disposed in the layer of the second conductivity type and a transfer gate disposed between the storage region and the charge-to-voltage conversion region.

3. The image sensor as in claim 2, further comprising a second shallow trench isolation region disposed in the layer of the second conductivity type laterally adjacent to the charge-to-voltage conversion region, wherein the second shallow trench isolation region comprises a trench formed in the layer of the second conductivity type that is filled with a dielectric material, and wherein an isolation layer of the second conductivity type is not disposed along the sidewalls and bottom of the trench.

4. The image sensor as in claim 2, further comprising a well of the second conductivity type disposed in the layer of the second conductivity type laterally adjacent to the charge-to-voltage conversion region.

5. The image sensor as in claim 1, further comprising a pinning layer of the second conductivity type disposed over the storage region and connected to the isolation layer disposed only along a sidewall of the trench immediately adjacent to the storage region.

6. The image sensor as in claim 1, wherein the image sensor is disposed in an image capture device.

7. An image sensor comprising an imaging area having a plurality of pixels with at least one pixel comprising:
a photodetector including a storage region of a first conductivity type disposed in a layer of a second conductivity type;
a charge-to-voltage conversion region of the first conductivity type disposed in the layer of the second conductivity type;
a transfer gate disposed between the photodetector and the charge-to-voltage conversion region;
a first shallow trench isolation region disposed in the layer of the second conductivity type laterally adjacent to the storage region, wherein the first shallow trench isolation region comprises a trench formed in the layer of the second conductivity type that is filled with a dielectric material;
an isolation layer of the second conductivity type disposed only partially along a bottom of the trench and only along a sidewall of the trench immediately adjacent to the storage region; and
a second shallow trench isolation region disposed in the layer of the second conductivity type laterally adjacent to the charge-to-voltage conversion region, wherein the second shallow trench isolation region comprises a trench formed in the layer of the second conductivity type that is filled with a dielectric material and an isolation layer of the second conductivity type is not disposed along a bottom and sidewalls of the trench.

8. The image sensor as in claim 7, further comprising a pinning layer of the second conductivity type disposed over the storage region and connected to the isolation layer disposed only along a sidewall of the trench immediately adjacent to the storage region.
